(19) United States
(12) Patent Application Publication
(10) Pub. No.: US 2025/0085056 A1
(43) Pub. Date: Mar. 13, 2025

(54) PROCESS CHAMBER SUBSTRATE TRANSFER

(71) Applicant: Applied Materials, Inc., Santa Clara, CA (US)

(72) Inventors: Wolfgang R. ADERHOLD, Cupertino, CA (US); Peter DEMONTE, Millbrae, CA (US)

(21) Appl. No.: 18/463,038

(22) Filed: Sep. 7, 2023

(51) Int. Cl. F27D 3/00

(52) U.S. Cl. CPC F27D 3/0084; F27D 2003/0051; F27D 2003/0091

(57) ABSTRACT

A processing system is provided including a first chamber and a second chamber. The first chamber includes: a chamber body enclosing an interior volume; an edge ring having a top and a bottom, the edge ring including a first ledge extending inwardly from the top and a second ledge extending inwardly relative to the first ledge. The first ledge is configured to support a substrate and the second ledge is configured to support a susceptor. The first chamber further includes a plurality of heating lamps positioned over the edge ring. The second chamber includes: a chamber body enclosing an interior volume; a first cooling plate; one or more robots in the interior volume of the second chamber, the one or more robots having one or more end effectors positioned over the first cooling plate; and a plurality of lift pins extending through the first cooling plate.

### BACKGROUND

Embodiments of the present disclosure generally relate to methods and related equipment for improving the transfer of substrates between chambers and the uniformity of processes performed on the substrates in process chambers, such as a rapid thermal processing.

### DESCRIPTION OF THE RELATED ART

The components used in electronic devices are continually becoming smaller. Manufacturing these smaller components presents challenges for handling the smaller components and the thinner substrates on which the components are formed. Furthermore, achieving process uniformity across a substrate during processes, such as rapid thermal processing, becomes more important as the size of the components to be formed continue to shrink.

Accordingly, there is a need for methods and equipment that can improve the handling of thinner substrates and improve the uniformity of the processes performed on the substrates.

### SUMMARY

In one embodiment, a processing system is provided comprising: a first chamber comprising: a chamber body enclosing an interior volume; an edge ring positioned in the interior volume, the edge ring having a top and a bottom, the edge ring including a first ledge extending inwardly from the top and a second ledge extending inwardly relative to the first ledge, wherein the first ledge is configured to support a substrate and the second ledge is configured to support a susceptor; and a plurality of heating lamps positioned over the edge ring; and a second chamber coupled with the first chamber, the second chamber comprising: a chamber body enclosing an interior volume; a first cooling plate; one or more robots in the interior volume of the second chamber, the one or more robots having one or more end effectors positioned over the first cooling plate; and a plurality of lift pins extending through the first cooling plate.

In another embodiment, a processing system is provided comprising: a first chamber comprising: a chamber body enclosing an interior volume; an edge ring positioned in the interior volume, the edge ring having a top and a bottom, the edge ring including a first ledge extending inwardly from the top and a second ledge extending inwardly relative to the first ledge, wherein the first ledge is configured to support a substrate and the second ledge is configured to support a susceptor; and a plurality of heating lamps positioned over the edge ring; and a second chamber coupled with the first chamber, the second chamber comprising: a chamber body enclosing an interior volume; and a robot having an end effector that includes a body, a first support and a second support, wherein the body has a top and a bottom, the first support and the second support are positioned on the top of the body, and the second support is movable relative to the first support from a first position to a second position.

In another embodiment, a method of processing a substrate is provided comprising: moving a substrate positioned on a susceptor into an interior volume of a process chamber; positioning the susceptor that is supporting the substrate on a support in the interior volume of the process chamber; performing a process on the substrate in the interior volume of the process chamber; and simultaneously removing the substrate and the susceptor from the interior volume of the process chamber after the process is performed.

In another embodiment, a susceptor for thermal processing of a substrate is provided, the susceptor comprising a disc-shaped body having a first surface, a second surface, and an outer edge connecting the first surface to the second surface, wherein the first surface configured to face a substrate during processing, the first surface is free of any holes, and the susceptor is configured to be repositioned between a process chamber and a cooldown chamber while a substrate is at least partially supported on the first surface.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1 shows a simplified view of a processing system, according to one embodiment.

FIG. 2 shows a side cross-sectional view of the RTP system shown in FIG. 1, according one embodiment.

FIG. 3 is a side view of the cooldown system shown in FIG. 1, according to one embodiment.

FIG. 4A is a partial side view of the end effector of the transfer robot from FIG. 1, according to one embodiment.

FIG. 4B is a partial side view of the end effector from FIG. 1 with the substrate and the susceptor positioned on the end effector, according to one embodiment.

FIG. 4C is a partial side view of the end effector from FIG. 1 with the substrate and the susceptor positioned on the end effector in a secured position, according to one embodiment.

FIG. 5 is a process flow diagram of a method for processing a substrate in the processing system of FIG. 1, according to one embodiment.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the present disclosure generally relate to processing systems for substrates (e.g., semiconductor substrates) that includes features for improving the handling of the substrates as well as improving the uniformity of the processes performed on the substrates. The processing systems disclosed are configured to transfer a substrate between different chambers in the processing system while the substrate is supported by an underlying support that can be used to support the substrate during the process, such as a susceptor. Supporting the substrate with the susceptor provides additional support for the substrate as the substrate is moved through the processing system. This additional support can be especially useful for handling thinner substrates (e.g., substrates having a thickness of around 100 micron or less than 100 micron) that may be more fragile than the thicker substrates that have been conventionally used. However, this additional support is also useful for substrates having more conventional thicknesses as well. The additional support can also be especially useful when the substrate is formed of material that is transparent to the radiation used to heat the substrate, and the additional substrate support is more opaque than the substrate.

In the following disclosure, the substrates can be supported by a susceptor when the substrate is inserted into a process chamber, such as a rapid thermal processing (RTP) chamber. Because the substrate is already supported by the susceptor before the substrate is inserted into the process chamber, the susceptor does not include any holes or plugs that are typically used to allow lift pins to raise the substrate above the susceptor inside the process chamber. These holes or plugs on the susceptor have often been locations of processing non-uniformities on the substrate as well as locations of damage (e.g., scratches) to the substrate. Because the susceptors provided in this disclosure do not include any holes or plugs for lift pins, these problems relating to process non-uniformities and damage to the areas of the substrate overlying these lift pin locations are eliminated.

Although the following disclosure mainly describes moving a substrate and a susceptor simultaneously into an RTP chamber, the benefits of this disclosure can be applied to any process chamber in which a substrate support, such as a susceptor, support ring, or other support, can be moved with the substrate. Some non-limiting examples of other process chambers in which a substrate support (e.g., a susceptor) can be moved into a process chamber while supporting the substrate include other types of substrate heating chambers, deposition chambers (e.g., chemical vapor deposition chambers, epitaxial deposition chambers, plasma enhanced deposition chambers), etching chambers, lithography chambers, and substrate cleaning chambers.

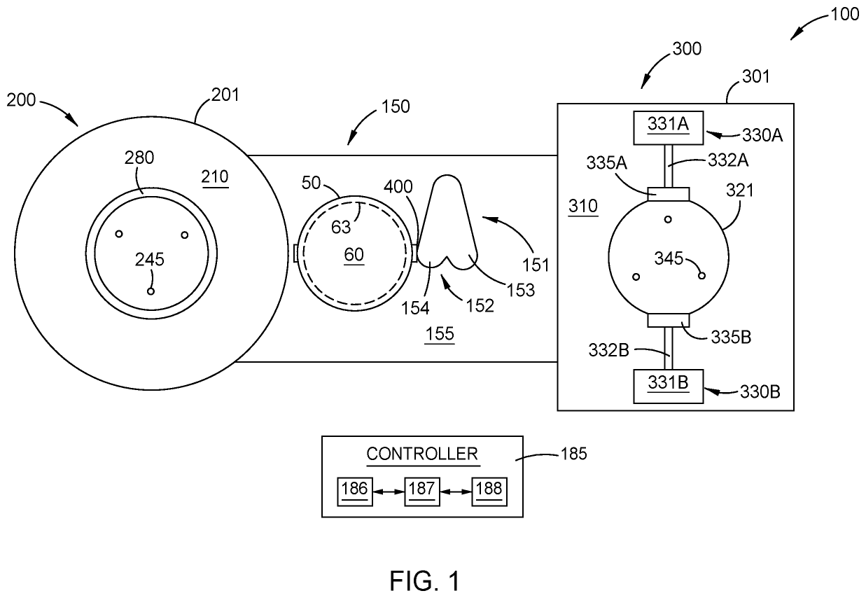

FIG. 1 shows a simplified view of a processing system 100, according to one embodiment. The processing system 100 includes a rapid thermal processing (RTP) system 200, a transfer chamber 150, a cooldown system 300, and a controller 185. The RTP system 200 includes a RTP chamber 201 (first chamber) having an interior volume 210. The transfer chamber 150 (second chamber) includes an interior volume 155. The cooldown system 300 includes a cooldown chamber 301 (second chamber) having an interior volume 310. In some embodiments, the components of the transfer chamber 150 and the cooldown chamber 301 can be included in a single chamber.

The transfer chamber 150 is positioned between the RTP chamber 201 and the cooldown chamber 301. The transfer chamber 150 can include a transfer robot 151. The transfer robot 151 can include an arm 152 and an end effector 400. The arm 152 can include an inner portion 153 and an outer portion 154. The inner portion 153 can be connected to an actuator (not shown) that is configured to rotate the inner portion 153, so that the end effector 400 can be extended and retracted. The outer portion 154 can also be coupled to an actuator (not shown) that is configured to rotate the outer portion 154 relative to the inner portion 153, so that the end effector 400 can be extended and retracted. In some embodiments, the end effector 400 can also include an actuator (not shown) that can be configured to rotate the end effector 400 relative to the outer portion 154.

The transfer robot 151 can be used to move a substrate 50 and a susceptor 60 to and from the interior volume 210 of the RTP chamber 201 and to and from the interior volume 310 of the cooldown chamber 301. The susceptor 60 is positioned below the substrate 50 and is shown in dashed lines to indicate that the susceptor 60 is below the substrate 50 in FIG. 1. Notably, in some embodiments, the top surface 61 (first surface) of the susceptor 60 does not include any holes or plugs that are conventionally used to allow for movement of lift pins through the susceptor and that have often been associated with damage (e.g., scratches) on the backside of the substrate 50. In some embodiments, the susceptor 60 has a smaller size (e.g., a smaller diameter) than the substrate 50 which the susceptor 60 supports. The transfer robot 151 can move the susceptor 60 and the substrate 50 at the same time. The susceptor 60 can help support the substrate 50 during movement of the substrate 50, for example into and out of the interior volume 210 of the RTP chamber 201 as well as into and out of the cooldown chamber 301.

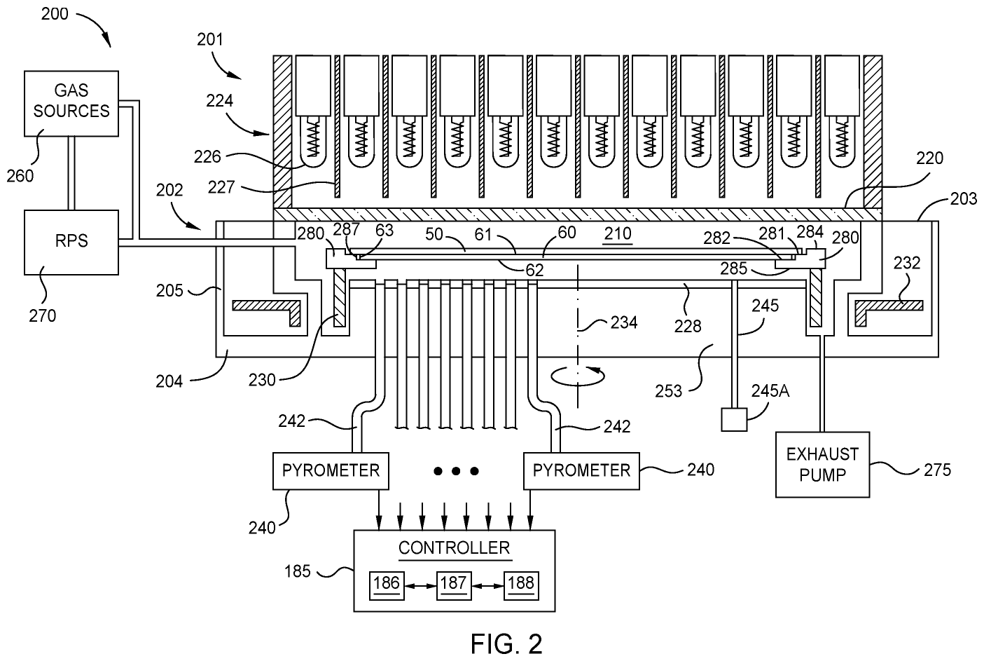

In some embodiments, the susceptor 60 has a disc-shaped body. The disc-shaped body can include the top surface 61 (first surface), a bottom surface 62 (second surface) (see FIG. 2), and an outer edge 63 connecting the top surface 61 with the bottom surface 62. The top surface 61 is configured to face and/or support a substrate 50 during processing. In some embodiments, the top surface 61 and well as the other surfaces 62, 63 can be completely free of unique features, such as holes that allow for the movement of lift pins.

The RTP chamber 201 can include a plurality of lift pins 245 and an edge ring 280. The lift pins 245 can raise above the top of the edge ring 280 when the substrate 50 and susceptor 60 are moved into or from the interior volume 210 of the RTP chamber 201. The lift pins 245 can lower to position the substrate 50 and susceptor 60 onto the edge ring 280 as described in further detail below.

The cooldown chamber 301 can include a first robot 330A, a second robot 330B, a first cooling plate 321, and a plurality of lift pins 345 in the interior volume 310 of the cooldown chamber 301. The lift pins 345 can raise above the top of the first cooling plate 321 when the substrate 50 and susceptor 60 are moved into or from the interior volume 310 of the cooldown chamber 301. The lift pins 345 can lower to position the substrate 50 and susceptor 60 onto the first cooling plate 321 as described in further detail below. Notably, the lift pins 245 (FIG. 2) and the lift pins 345 do not directly contact the substrate 50, which can eliminate problems, such as damage that can result when a lift pin touches the backside of a substrate. Lift pins can often damage the backside of a substrate with the likelihood of damage being higher when the substrates are heated to elevated temperatures, such as after RTP is performed on a substrate.

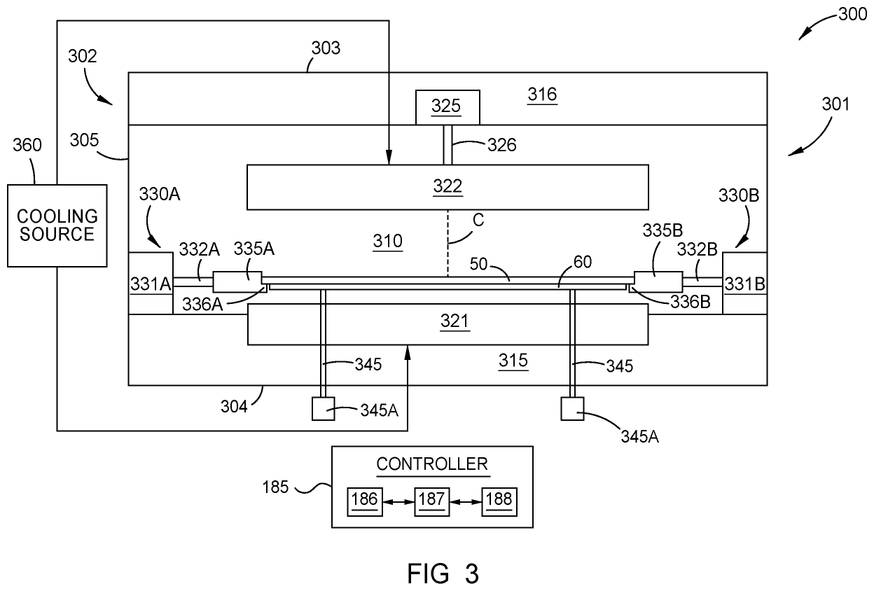

Each robot 330 can include an actuator 331, a shaft 332, and an end effector 335. The end effectors 335 can be used to grip and/or support the substrate 50 around the outer edge of the substrate 50, so that the substrate 50 can be removed from susceptor 60. After the substrate 50 is contacted around the outer edge of the substrate 50 by the end effectors 335A, 335B, the lift pins 345 can lower, so that the susceptor 60 is lowered relative to the substrate 50. After the susceptor 60 is lowered, an external robot (not shown) can remove the substrate 50 from the end effectors 335A, 335B and from the cooldown chamber 301, and then subsequently position another substrate 50 in the cooldown chamber 301. In some embodiments, a single robot with one or more end effectors can be used in the cooldown chamber 301. In one embodiment with a single robot having two end effectors, this single robot can position the end effectors closer to or further away from each other in a similar manner as described herein for the robots 330A, 330B. In FIG. 3, each robot 330 can be positioned in an outer location in which the end effectors 335 do not overlie the lift pins 345. This location enables the robots 330 to extend to contact the substrate 50 around the edge of the substrate 50.

The RTP system 200 further includes the controller 185 for controlling processes performed by the processing system 100. The controller 185 can be any type of controller used in an industrial setting, such as a programmable logic controller (PLC). The controller 185 includes a processor 187, a memory 186, and input/output (I/O) circuits 188. The controller 185 can further include one or more of the following components (not shown), such as one or more power supplies, clocks, communication components (e.g., network interface card), and user interfaces typically found in controllers for semiconductor equipment.

The memory 186 can include non-transitory memory. The non-transitory memory can be used to store the programs and settings described below. The memory 186 can include one or more readily available types of memory, such as read only memory (ROM) (e.g., electrically erasable programmable read-only memory (EEPROM), flash memory, floppy disk, hard disk, or random access memory (RAM) (e.g., non-volatile random access memory (NVRAM).

The processor 187 is configured to execute various programs stored in the memory 186, such as programs configured to perform thermal processes in the RTP chamber 201 as well as movement of the substrate 50 and susceptor 60 through the processing system 100. During execution of these programs, the controller 185 can communicate to I/O devices (e.g., inputs, such as sensors and outputs, such as actuators) through the I/O circuits 188. For example, during execution of these programs and communication through the I/O circuits 188, the controller 185 can control outputs, such as raising and lowering lift pins 245, 345 and receive information from inputs, such as temperature sensors in the RTP chamber 201. The memory 186 can further include various operational settings used to control the processing system 100. For example, the settings can include temperature setpoints and durations for heating the substrate 50 in the RTP chamber 201.

FIG. 2 shows a side cross-sectional view of the RTP system 200, according one embodiment. The RTP system 200 includes the RTP chamber 201, gas sources 260, a remote plasma source 270, and an exhaust pump 275.

In some embodiments, gases from the gas sources 260 can be provided to the remote plasma source 270 to generate a plasma that is then provided to the RTP chamber 201 to clean the interior of the RTP chamber 201. In other embodiments, gases from the gas sources 260 can be provided to the RTP chamber 201 without going through the remote plasma source 270, and these gases can be heated by the RTP chamber 201 to cause the heated gases to form plasma species (e.g., radicals) to clean the interior of the RTP chamber 201. The gases from the gas sources 260 can include cleaning gases (e.g., hydrogen and oxygen) as well as gases for performing a purge (e.g., an inert gas or nitrogen). The exhaust pump 275 can be used to exhaust gases from the interior of the RTP chamber 201 as well as to control the pressure in the interior volume of the RTP chamber 201.

The RTP chamber 201 includes a chamber body 202. The chamber body 202 encloses the interior volume 210. The chamber body 202 includes a top 203, a bottom 204, and one or more sides 205 connecting the top 203 with the bottom 204. The RTP chamber 201 includes a transparent window 220 that can form part of the top 203 of the chamber body 202.

The RTP chamber 201 includes an edge ring 280. When the substrate 50 and the susceptor 60 are inserted in the interior volume 210, the substrate 50 and the susceptor 60 can be positioned on the lift pins 245 when the lift pins 245 are raised above the edge ring 280. The substrate 50 and the susceptor 60 can be positioned on the lift pins 245 through a port (not shown), such as a slit valve. The lift pins 245 can then be lowered to position susceptor 60 and the substrate 50 on the edge ring 280.

The edge ring 280 includes a top surface 284, a bottom surface 285, a first ledge 281, a second ledge 282, and a sidewall 287. The sidewall 287 can connect the first ledge 281 with the second ledge 282. The first ledge 281 extends inwardly relative to the top surface 284 towards a central axis 234 of the interior volume 210. The first ledge 281 extends inwardly at a vertical location below the top surface 284 of the edge ring 280 and above the second ledge 282 of the edge ring 280. The second ledge 282 extends inwardly relative to the first ledge 281 towards the central axis 234 of the interior volume 210. The second ledge 282 extends inwardly at a vertical location below the first ledge 281 of the edge ring 280 and above the bottom surface 285 of the edge ring 280. The substrate 50 can be positioned on the first ledge 281 of the edge ring 280 during processing. The susceptor 60 can be positioned on the second ledge 282 of the edge ring 280 during processing.

The RTP chamber 201 further includes a rotatable cylinder 230 and a rotatable flange 232. The edge ring 280 is positioned on or connected to (e.g., mounted to) the rotatable cylinder 230. The rotatable cylinder 230 is magnetically coupled to the rotatable flange 232. A rotor (not shown) rotates the rotatable flange 232 about the central axis 234. The rotation of the flange 232 causes the rotatable cylinder 230 and edge ring 280 to rotate along with the substrate 50 and the susceptor 60 that are positioned on the edge ring 280 during processing.

As mentioned above, the top surface 61 of susceptor 60 does not include any holes, such as holes typically used for lift pins. In some embodiments, there are no holes, recesses, or other unique features on any surface of the susceptor 60, and the body of the susceptor 60 can also be uniform in a radial direction as well as along the azimuth. This higher level of uniformity across the susceptor 60 allows for improved uniformity in the thermal performance of the susceptor 60, which improves the thermal uniformity across the substrate 50 in the radial direction and along the azimuth when a process (e.g., RTP) is performed on the substrate 50. The dual ledges 281, 282 of the edge ring 280 allows for the gaps to remain quite small (1) between the substrate 50 and the susceptor 60, (2) between the susceptor 60 and the edge ring 280, and (3) between the substrate 50 and the edge ring 280 during processing, which can also improve thermal performance. A small gap is maintained between these components to account for thermal expansion. In some embodiments, the susceptor 60 can be sized to position the outer edge 63 of the susceptor 60 at a distance from about 0.01 mm to about 5 mm, such as from about 0.1 mm to about 0.5 mm from the sidewall 287 of the edge ring 280 when the susceptor 60 is positioned on the second ledge 282. For example, in some embodiments, the diameter of the susceptor 60 is smaller than the diameter of the second ledge 282 (i.e., from the center of the susceptor 60 to the sidewall 287) by a distance from about 0.01 mm to about 5 mm, such as from about 0.1 mm to about 0.5 mm.

In some embodiments, the thermal performance of the susceptor 60 can have a very high degree of uniformity in the radial direction and along the azimuth. For example, in some embodiments of the susceptor 60, the variation in thermal performance (e.g., thermal load) is less than 1%, such as less than 0.1%, such as less than 0.01% along the azimuth around the center of the susceptor 60 (i.e., for 360 degrees) for each radial distance from the center of the susceptor 60 to the outer edge of the susceptor 60. Similarly, for each angular location, the variation in thermal performance (e.g., thermal load) is less than 5%, such as less than 1%, such as less than 1% in the radial direction from the center of the susceptor 60 to the outer edge of the susceptor 60. Conventional susceptors having unique features at locations across the surface facing the substrate, such as holes for lift pins, cannot achieve this level of thermal uniformity.

The RTP chamber 201 further includes a reflector 228 positioned below the edge ring 280. The reflector 228 can be used to reflect radiation back towards the substrate 50 and susceptor 60 that are positioned on the edge ring 280 during processing. The reflector 228 can include holes that allow the lift pins 245 to extend and retract through the reflector 228 to raise and lower the susceptor 60 and substrate 50. Each lift pin 245 can be connected to a lift pin actuator 245A. Each lift pin actuator 245A can be positioned below the reflector 228.

The RTP chamber 201 further includes a heating apparatus 224 positioned over the chamber body 202. The heating apparatus 224 can include a plurality of lamps 226. In some embodiments, the plurality of lamps 226 can be positioned in respective reflective tubes 227 that are arranged in a hexagonal close-packed array above the transparent window 220. In some embodiments, the lamps 226 are high-intensity tungsten-halogen lamps. In some embodiments, the heating apparatus 224 includes hundreds or thousands of the lamps 226. The heating apparatus 224 can be configured to rapidly heat components in the interior volume 210 at rates greater than 100° C./second, such as greater than 300° C./second to temperatures from 600° C. to 1350° C.

During processing, the reflector 228 reflects radiation emitted from the substrate 50 and susceptor 60 back toward the substrate 50 and the susceptor 60. In some embodiments, the reflector 228 can be supported on a base 253. The base 253 can form part of the chamber bottom 204. In some embodiments, the base 253 can be made of metal to heat sink excess radiation, especially during cool down portions of a process. In some embodiments, a cooling fluid (e.g., water) can be circulated through the base 253 during a process performed on a substrate.

In some embodiments, the susceptor 60 can be formed of silicon carbide, a base material (e.g., a carbide) coated with silicon carbide, aluminum oxide (Al₂O₃) or from one or more ceramic materials. The reflector 228 can be formed of materials, such as copper, copper coated with nickel, gold, aluminum (e.g., polished aluminum), and aluminum coated with nickel.

In some embodiments, the lamps 226 can be arranged in a ring-like pattern about the central axis 234. Control circuitry can be used to vary the voltage delivered to the lamps 226 in the different zones to control the radial distribution of radiant energy during processes, so that the temperature of different locations on the substrate 50 or other components, such as the reflector 228 can be controlled during a process.

The RTP chamber 201 can further include a plurality of pyrometers 240 and a plurality of light pipes 242. Each light pipe 242 can extend from one of the pyrometers 240 to a location below the edge ring 280. For example, each light pipe 242 can extend to a different aperture in the reflector 228. Each pyrometer 240 can receive radiation through a corresponding light pipe 242 to monitor temperatures at different locations (e.g., different radial locations) on the substrate 50 during processing.

FIG. 3 is a side view of the cooldown system 300 from FIG. 1, according to one embodiment. The cooldown system 300 includes the cooldown chamber 301 and a cooling source 360. In one embodiment, the cooling source 360 is a cooling water source that can provide cooling water to the cooldown chamber 301 to assist in cooling the substrate 50 and the susceptor 60 after the substrate 50 and susceptor 60 are heated to high temperatures in the RTP chamber 201 (see FIG. 2).

The cooldown chamber 301 includes a chamber body 302 enclosing the interior volume 310 of the cooldown chamber 301. The chamber body 302 includes a top 303, a bottom 304, and one or more sidewalls 305. The cooldown chamber 301 further includes a base 315 and a first cooling plate 321 positioned over (e.g., on) the base 315. The cooling source 360 can be fluidly coupled to the first cooling plate 321. Cooling fluid can be provided to the first cooling plate 321 from the cooling source 360 to assist in cooling the substrate 50 and the susceptor 60.

The cooldown chamber 301 further includes the lift pins 345. Each lift pin 345 can be coupled to a lift pin actuator 345A. Each lift pin actuator 345A can be configured to raise and lower the lift pin 345 that is coupled to that lift pin actuator 345A. The base 315 and the first cooling plate 321 can each include holes to allow the movement of the lift pins 345 to raise and lower the susceptor 60 and the substrate 50 relative to the top surface of the first cooling plate 321.

The cooldown chamber 301 can further include a second cooling plate 322 positioned over the first cooling plate 321. The cooling source 360 can be fluidly coupled to the second cooling plate 322. Cooling fluid can be provided to the second cooling plate 322 from the cooling source 360 to assist in cooling the substrate 50 and the susceptor 60. In some embodiments, the second cooling plate 322 can be coupled to an actuator 325 through a shaft 326. The actuator 325 can be configured to move the shaft 326 to raise and lower the second cooling plate 322, so that the second cooling plate 322 can be positioned closer to the substrate 50 during cooling. The actuator 325 can extend the shaft 326 and second cooling plate 321 from a primary position to a secondary position that is located closer to the first cooling plate 321 than the primary position. In some embodiments, the actuator 325 can mounted to or in a ceiling 316 of the cooldown chamber 301.

The cooldown chamber 301 further includes the first robot 330A and the second robot 330B. The robots 330 can be used to remove the substrate 50 from the susceptor 60 and to receive a new substrate 50 when a new substrate 50 is inserted into the cooldown chamber 301 by an external robot (not shown). As described above, each robot 330 can include an actuator 331, a shaft 332, and an end effector 335. The shaft 332 connects the actuator 331 to the corresponding end effector 335. Each actuator 331 can be configured to extend and retract the shaft 332 horizontally to move the corresponding end effectors 335 closer to or further away from a central vertical axis C of the interior volume 310, so that the end effectors 335 can contact the substrate 50. Each actuator 331 can extend the shaft 332 from a first position to a second position in which the corresponding end effector 335 can contact the substrate 50 at or near the edge of the substrate 50.

In some embodiments, each end effector 335 can include an extension 336. The extension 336 extends inwardly towards the central vertical axis C relative to the remainder of the end effector 335. The extension 336 can be configured to be positioned under the outer edge of the substrate 50 when the substrate 50 is removed from the susceptor 60. In some embodiments, each actuator 331 can also be configured to move the shaft 332 and corresponding end effector 335 vertically. For example, each actuator 331 can position the extension 336 of the corresponding end effector 335 under the outer edge of the substrate and then the actuator 331 can move the end effector 335 upward to assist with (1) removing the substrate 50 from the susceptor 60 or (2) removing a new substrate 50 from an external robot (not shown) when the external robot inserts the new substrate 50 into the cooldown chamber 301.

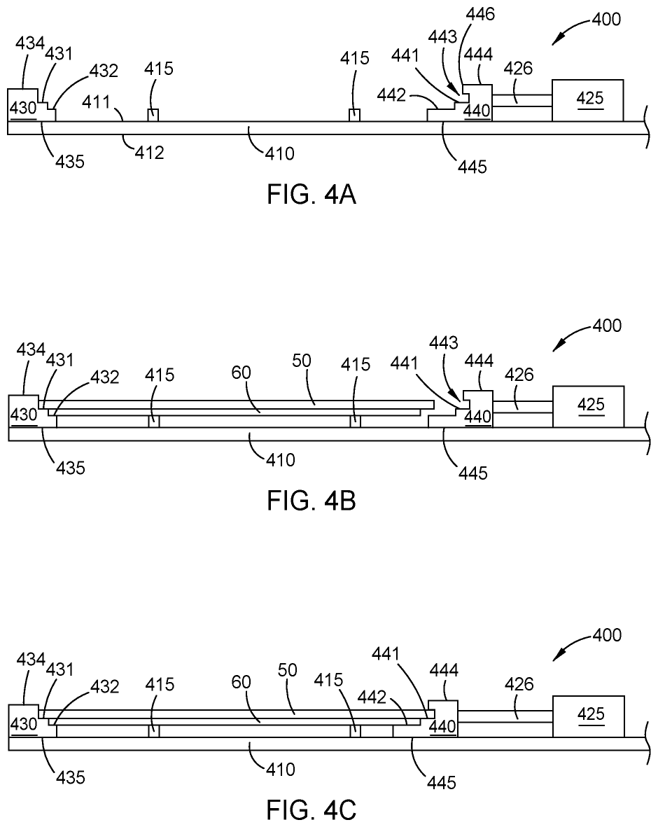

FIG. 4A is a partial side view of the end effector 400 of the transfer robot 151 from FIG. 1, according to one embodiment. The end effector 400 includes a blade 410 (body), a plurality of support pins 415, a first support 430, and a second support 440. The blade 410 includes a top surface 411 and a bottom surface 412. The plurality of pins 415, the first support 430, and the second support 440 are positioned over (e.g., directly on) the top surface 411 of the blade 410. The plurality of pins 415 can include any number of pins, such as two, three, or greater than ten.

The first support 430 includes a top surface 434 and a bottom surface 435. The first support 430 further includes a first ledge 431 and a second ledge 432 extending inwardly towards the second support 440. The first ledge 431 is located below the top surface 434 and above the second ledge 432. The second ledge 432 is located below the first ledge 431 and above the bottom surface 435. The second ledge 432 horizontally extends further relative to an inner edge 436 of the top surface 434 towards the second support 440 than the first ledge 431 extends in the same direction. The first ledge 431 is configured to support the substrate 50. The second ledge 432 is configured to support the susceptor 60.

The second support 440 can be positioned 180 degrees apart from the first support 430. The second support 440 includes a top surface 444 and a bottom surface 445. The second support 440 further includes a first ledge 441 and a second ledge 442 extending inwardly towards the first support 430. The first ledge 441 is located below the top surface 444 and above the second ledge 442. The second ledge 442 is located below the first ledge 441 and above the bottom surface 445. The second ledge 442 horizontally extends further relative to an inner edge 446 of the top surface 444 towards the first support 430 than the first ledge 441 extends in the same direction. The first ledge 441 is configured to support the substrate 50. The second support 440 further includes a recess 443 between the first ledge 441 and the top surface 444 of the second support 440. The top of the second support 440 can overhang the first ledge 441. The recess 443 can have a height that is slightly greater than the thickness of the substrate 50. A portion of the edge of the substrate 50 can be positioned in the recess 443 as described below. In some embodiments, the recess 443 can have a height that is slightly greater than the thickness of the substrate 50, so that the recess 443 can assist in preventing movement of the substrate relative to the supports 430, 440 when the substrate 50 is transferred between chambers. The second ledge 442 is configured to support the susceptor 60.

In one embodiment, the first support 430 is configured to be stationary while the second support 440 is configured to be a movable support. The end effector 400 can further include an actuator 425 and a shaft 426 that are positioned over the top surface 411 of the blade 410. The second support 440 can be coupled to the actuator 425 through the shaft 426. The actuator 425 can be configured to extend and retract the shaft 426 to move the second support 440 closer to or further from the first support 430. For example, the actuator 425 can extend the shaft 426 from a first position to a second position that is closer to the first support 430 than the first position.

FIG. 4B is a partial side view of the end effector 400 from FIG. 1 with the substrate 50 and the susceptor 60 positioned on the end effector 400, according to one embodiment. The susceptor 60 can be positioned on the support pins 415 and the second ledge 432 of the first support 430. The substrate 50 is positioned on top of the susceptor 60. The substrate 50 can additionally be supported by the first ledge 431 of the first support 430. The substrate 50 and the susceptor 60 can be in the position shown in FIG. 4B, for example after the lift pins 245 (see FIG. 2) or the lift pins 345 (see FIG. 3) lower the susceptor 60 onto the end effector 400.

FIG. 4C is a partial side view of the end effector 400 from FIG. 1 with the substrate 50 and the susceptor 60 positioned on the end effector 400 in a secured position, according to one embodiment. The view in FIG. 4C is the same as the view in FIG. 4B except that the substrate 50 and the susceptor 60 are also supported and secured by the second support 440. The actuator 425 has extended the shaft 426 to move the second support 440 from the non-supporting position shown in FIG. 4B to the supporting position shown in FIG. 4C. In the supporting position of FIG. 4C, the substrate 50 is supported by the first ledge 441 of the second support 440, and the susceptor 60 is supported by the second ledge 442 of the second support 440. A portion of the outer edge of the substrate 50 is also moved into the recess 443 (see FIG. 4B), which can assist in securing the substrate 50 during movement of the end effector 400.

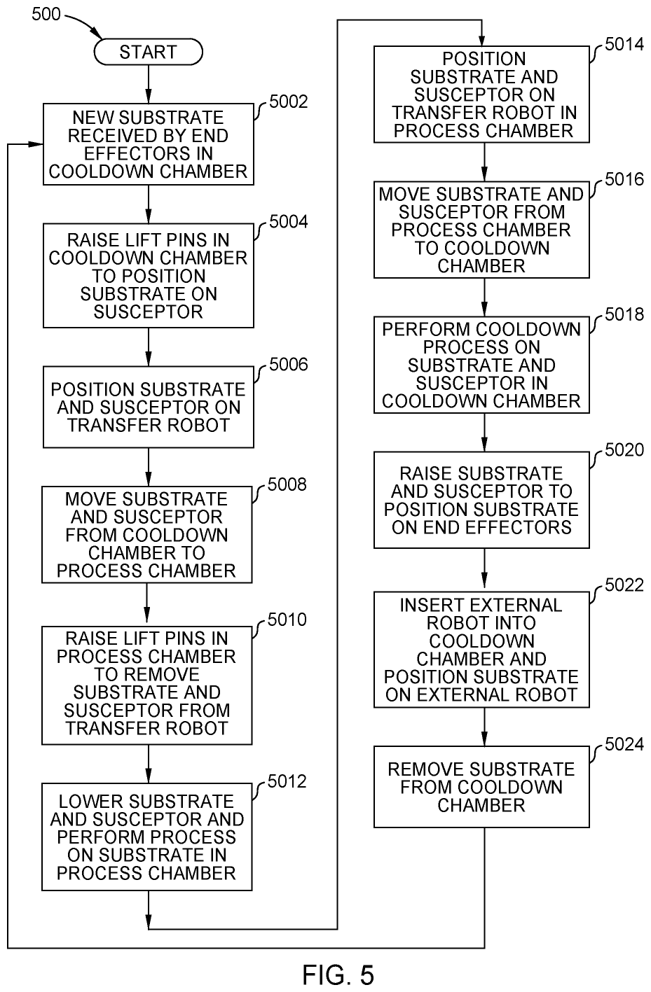

FIG. 5 is a process flow diagram of a method 5000 for processing a substrate 50 in the processing system 100 from FIG. 1, according to one embodiment. The method 5000 is described in reference to FIGS. 1-5. The method 5000 can be executed by the controller 185.

The method begins at block 5002. At block 5002 with reference to FIG. 3, a new substrate 50 is provided to the interior volume 310 of the cooldown chamber 301 and the new substrate 50 is received by the end effectors 335A, 335B. The new substrate 50 can be inserted into the interior volume 310 of the cooldown chamber 301 by an external robot (not shown). At block, the susceptor 60 is already on the first cooling plate 321 or on the lift pins 345 in the interior volume 310 of the cooldown chamber 301 when the new substrate 50 is provided to the interior volume 310 of the cooldown chamber 301.

In one embodiment, the external robot can lower the new substrate 50 onto the extensions 336 of the end effectors 335 before the external robot is removed from the cooldown chamber 301. In another embodiment, the actuators 331 can raise the end effectors 335 to lift the new substrate 50 from the external robot before the external robot is removed from the cooldown chamber 301. In some embodiments, the end effectors 335 are extended in the horizontal direction, so that the substrate 50 can be gripped by the end effectors 335. After the substrate 50 is gripped by the end effectors 335, the end effectors 335 can be raised or the external robot (not shown) can be lowered and removed from the cooldown chamber 301.

At block 5004 with reference to FIG. 3, the lift pins 345 are raised to raise the susceptor 60 to a height where the susceptor 60 contacts the bottom of the substrate 50 or to a height where the susceptor 60 lifts the substrate 50 from the end effectors 335. In some embodiments, the actuators 331 can retract the end effectors 335 away from the substrate 50 after the substrate 50 is supported by the susceptor 60.

At block 5006 with reference to FIGS. 1, 3, and 4A-4C, the end effector 400 of the transfer robot 151 is inserted into the interior volume 310 of the cooldown chamber 301, and the lift pins 345 are lowered to position the susceptor 60 and the substrate 50 onto the end effector 400, for example as shown in FIG. 4B. The actuator 425 can then move the second support 440 to the position shown in FIG. 4C, so that the second support 440 provides support to the susceptor 60 and the substrate 50. In the position shown in FIG. 4C, the substrate 50 is positioned on the first ledge 441 and secured in the recess 443 of the second support 440, which helps prevent any unintended movement of the substrate 50 when the substrate 50 is moved by the transfer robot 151.

At block 5008 with reference to FIGS. 1, 2, 3, 4B, and 4C, the transfer robot 151 simultaneously moves the susceptor 60 and the substrate 50 (1) from the interior volume 310 of the cooldown chamber 301, (2) through the interior volume 155 of the transfer chamber 150, and (3) into the interior volume 210 of the RTP chamber 201. The transfer robot 151 can keep the second support 440 in the position shown in FIG. 4C while moving the substrate 50 and susceptor 60 from the cooldown chamber 301 to the RTP chamber 201. After the transfer robot 151 positions the substrate 50 and the susceptor 60 in the intended position over the edge ring 280 of the RTP chamber 201, the transfer robot 151 can move the second support 440 back to the position shown in FIG. 4B to allow the substrate 50 and susceptor 60 to easily be removed from the end effector 400 of the transfer robot 151.

At block 5010 with reference FIGS. 2 and 4B, the lift pins 245 in the RTP chamber 201 are raised to lift the susceptor 60 and the substrate 50 from the end effector 400 of the transfer robot 151. The end effector 400 is then removed from the interior volume 210 of the RTP chamber 201.

At block 5012 with reference to FIG. 2, the lift pins 245 are lowered to position the substrate 50 and the susceptor 60 on the edge ring 280 and a process, such as RTP, is performed on the substrate 50. The substrate 50 and the susceptor 60 can be positioned on the edge ring 280 as shown in FIG. 2 during the process performed on the substrate 50.

At block 5014, with reference to FIGS. 2, 4B, and 4C, the substrate 50 and the susceptor 60 are positioned back on the end effector 400 of the transfer robot 151 after the process performed on the substrate 50 at block 5012 is complete. After the process on the substrate 50 is completed, the lift pins 245 are raised to lift the substrate 50 and the susceptor 60 above the edge ring 280, and the end effector 400 of the transfer robot 151 is inserted into the interior volume 210 below the substrate 50 and the susceptor 60. The lift pins 245 are then lowered to position the substrate 50 and the susceptor 60 onto the end effector 400 in the position shown in FIG. 4B. The transfer robot 151 then moves the second support 440 to the position shown in FIG. 4C, so that the susceptor 60 and the substrate 50 are in a secured position for movement out of the RTP chamber 201.

At block 5016 with reference to FIGS. 1, 2, 3, 4B, and 4C, the transfer robot 151 simultaneously moves the susceptor 60 and the substrate 50 (1) from the interior volume 210 of the RTP chamber 201, (2) through the interior volume 155 of the transfer chamber 150, and (3) into the interior volume 310 of the cooldown chamber 301. The transfer robot 151 can keep the second support 440 in the position shown in FIG. 4C while moving the substrate 50 and susceptor 60 from the RTP chamber 201 to the cooldown chamber 301. After the transfer robot 151 positions the substrate 50 and the susceptor 60 in the intended position over lift pins 345 in the cooldown chamber 301, the transfer robot 151 can move the second support 440 back to the position shown in FIG. 4B to allow the substrate 50 and susceptor 60 to easily be removed from the end effector 400 of the transfer robot 151. During blocks 5008 and 5016, the susceptor 60 is configured to be repositioned between the RTP chamber 201 and the cooldown chamber 301 while the substrate 50 is at least partially supported on the first surface 61 of the susceptor 60. The regions of the substrate 50 near the outer edge of the substrate 50 can be supported by the ledges 431, 441 of the supports 430, 440 on the end effector 400.

At block 5018 with reference to FIG. 3, a cooldown process is performed on the substrate 50 and susceptor 60 after the lift pins 345 are: (1) raised to remove the substrate 50 and susceptor 60 from the end effector 400; and (2) lowered to position the substrate 50 and susceptor 60 onto the first cooling plate 321. The end effector 400 can be removed from the interior volume 310 after the substrate 50 and the susceptor 60 are positioned on the lift pins 345. Cooling fluid (e.g., cooling water) can be provided to flow through the first cooling plate 321 to increase the rate at which the substrate 50 and susceptor 60 cool down.

In embodiments that include the second cooling plate 322, cooling fluid (e.g., cooling water) can be provided to flow through the second cooling plate 322 to increase the rate at which the substrate 50 and susceptor 60 cool down. In some of these embodiments, the second cooling plate 322 can be lowered to be positioned closer to the substrate 50 and the first cooling plate 321 to further increase the cooling rate for the substrate 50 and susceptor 60. In some embodiments, the substrate 50 can be separated from the susceptor 60 prior to cooling, so that the bottom surface of the substrate 50 and the top of the susceptor 60 are not covered. For example, the substrate 50 can be supported by the end effectors 335 and the susceptor 60 can be lowered onto the first cooling plate 321. Furthermore, in some embodiments, the cooldown chamber 301 can be modified to be a batch cooldown chamber in which multiple substrates and susceptors can be cooled down at the same time. In some of these batch cooldown chamber embodiments, the cooldown chamber can include cooling plates similar to cooling plates 321, 322 that that are spaced apart horizontally and/or vertically. A batch cooldown chamber can be useful, for example when the cooldown process takes longer than the process (e.g., RTP) performed in the process chamber.

In some embodiments, a cooldown chamber can include a stack of three or more cooling plates for cooling three or more pairs of substrates and susceptors. In some of these embodiments, the cooldown chamber can further include a single common robot (e.g., robot 330A) that can be configured to separate a substrate 50 from a susceptor 60 on each cooling plate in the cooldown chamber.

At block 5020 with reference to FIG. 3, after the substrate 50 has cooled to a target temperature, the lift pins 345 can raise the substrate 50 and susceptor 60 above the first cooling plate 321, and the robots 330 can be used to position the substrate 50 on the end effectors 335 of the robots 330. The robots 330A, 330B can extend the end effectors 335 to a position at which the end effectors 335 can support the substrate 50. Before raising the lift pins 345, the second cooling plate 322 can be raised if the second cooling plate was lowered during block 5018. After the substrate 50 is positioned on and/or gripped by the end effectors 335, the lift pins 345 can be lowered, so that the susceptor 60 is not in the way when the substrate 50 is removed from the cooldown chamber 301. In some embodiments, the susceptor 60 can lowered back onto the first cooling plate 321, so that the susceptor 60 can continue to cool. In some embodiments, the cooldown chamber 301 can include one or more temperature sensors (not shown) to assist in determining when the substrate 50 has cooled to a target temperature. In other embodiments, the controller 185 can execute a timer to determine when the substrate has cooled to a target temperature.

At block 5022 with reference to FIG. 3, an external robot (not shown) can be inserted into the interior volume 310 of the cooldown chamber 301, and the substrate 50 can be positioned on the external robot. The external robot can be inserted below the substrate 50. In some embodiments, the external robot can raise in the interior volume 310 to lift the substrate 50 from the end effectors 335A, 335B. In other embodiments, the robots 330 can lower the corresponding end effectors 335A, 335B to lower the substrate 50 onto the external robot. In some embodiments, the external robot can have an end effector with a similar shape as the blade 410 of the end effector 400 (see FIG. 1).

At block 5024 with reference to FIG. 3, the external robot (not shown) removes the substrate 50 from the interior volume 310 of the cooldown chamber 301. After block 5024, the method 5000 can be repeated to process another substrate 50. The method 5000 can be repeated any number of times.

While the foregoing is directed to examples of the present disclosure, other and further examples of the disclosure may be devised without departing from the basic scope thereof, and the scope thereof is determined by the claims that follow.

What is claimed is:

1. A processing system comprising:
a first chamber comprising:
a chamber body enclosing an interior volume;
an edge ring positioned in the interior volume, the edge ring having a top and a bottom, the edge ring including a first ledge extending inwardly from the top and a second ledge extending inwardly relative to the first ledge, wherein the first ledge is configured to support a substrate and the second ledge is configured to support a susceptor; and
a plurality of heating lamps positioned over the edge ring; and
a second chamber coupled with the first chamber, the second chamber comprising:
a chamber body enclosing an interior volume;
a first cooling plate;
one or more robots in the interior volume of the second chamber, the one or more robots having one or more end effectors positioned over the first cooling plate; and
a plurality of lift pins extending through the first cooling plate.

2. The processing system of claim 1, wherein
the one or more end effectors are positioned at an outer location in the interior volume of the second chamber, and
the outer location does not overlie the plurality of lift pins.

3. The processing system of claim 1, wherein each robot of the one or more robots is configured to move one of the one or more end effectors in a horizontal direction.

4. The processing system of claim 1, further comprising a controller configured to activate the one or more robots to move the one or more end effectors towards a center of the interior volume of the second chamber from a first position to a second position.

5. The processing system of claim 4, wherein the one or more end effectors are configured to contact an edge of a substrate in the second position and the controller is further configured to lower the plurality of lift pins when the one or more end effectors are in the second position.

6. The processing system of claim 1, further comprising a susceptor positioned on the second ledge of the edge ring, wherein the susceptor has a diameter that is smaller than the diameter of the second ledge by a distance from about 0.1 mm to about 0.5 mm.

7. The processing system of claim 1, wherein the second chamber further comprises a second cooling plate positioned over the first cooling plate in the interior volume of the second chamber.

8. The processing system of claim 7, further comprising an actuator coupled to the second cooling plate, the actuator configured to move the second cooling plate from a primary position to a secondary position, wherein the secondary position is located closer to the first cooling plate than the primary position.

9. A processing system comprising:
a first chamber comprising:
a chamber body enclosing an interior volume;
an edge ring positioned in the interior volume, the edge ring having a top and a bottom, the edge ring including a first ledge extending inwardly from the top and a second ledge extending inwardly relative to the first ledge, wherein the first ledge is configured to support a substrate and the second ledge is configured to support a susceptor; and
a plurality of heating lamps positioned over the edge ring; and
a second chamber coupled with the first chamber, the second chamber comprising:
a chamber body enclosing an interior volume; and
a robot having an end effector that includes a body, a first support and a second support, wherein the body has a top and a bottom, the first support and the second support are positioned on the top of the body, and the second support is movable relative to the first support from a first position to a second position.

10. The processing system of claim 9, wherein
the first support includes a top, a bottom, a first ledge, and a second ledge,
the first ledge extends towards the second support, and
the second ledge extends from the first ledge towards the second support.

11. The processing system of claim 9, wherein
the second support includes a top, a bottom, a first ledge, and a second ledge,
the first ledge extends towards the first support, and
the second ledge extends from the first ledge towards the first support.

12. The processing system of claim 11, wherein the second support includes a recess positioned between the first ledge and the top of the second support.

13. The processing system of claim 9, further comprising a susceptor positioned on the second ledge of the edge ring, wherein the susceptor has a diameter that is smaller than the diameter of the second ledge by a distance from about 0.1 mm to about 0.5 mm

14. A method of processing a substrate comprising:
moving a substrate positioned on a susceptor into an interior volume of a process chamber;
positioning the susceptor that is supporting the substrate on a support in the interior volume of the process chamber;
performing a process on the substrate in the interior volume of the process chamber; and
simultaneously removing the substrate and the susceptor from the interior volume of the process chamber after the process is performed.

15. The method of claim 14, wherein the substrate has a larger diameter than the susceptor.

16. The method of claim 14, wherein the susceptor includes a top surface without any holes.

17. The method claim 14, further comprising:
moving the susceptor that is supporting the substrate to a second chamber; and
separating the substrate from the susceptor in the second chamber.

18. The method of claim 17, further comprising removing the substrate from the second chamber after separating the substrate from the susceptor.

19. The method of claim 18, further comprising positioning a new substrate on the susceptor in the second chamber after separating the substrate from the susceptor.

20. The method of claim 17, further comprising positioning the susceptor on a first cooling plate in the second chamber and providing a cooling fluid to flow through the first cooling plate when the susceptor is positioned on the first cooling plate.

21. A susceptor for thermal processing of a substrate, the susceptor comprising a disc-shaped body having a first surface, a second surface, and an outer edge connecting the first surface to the second surface, wherein
the first surface configured to face a substrate during processing,
the first surface is free of any holes,
the susceptor is configured to be repositioned between a process chamber and a cooldown chamber while a substrate is at least partially supported on the first surface.

22. The susceptor of claim 21, wherein a variation in thermal load across the first surface of the susceptor is less than 1% along the azimuth completely around a center of the susceptor for each radial distance from the center of the susceptor to the outer edge of the susceptor.
